(19) United States
(12) Patent Application Publication
(10) Pub. No.: US 2025/0231598 A1
(43) Pub. Date: Jul. 17, 2025

(54) SYSTEMS AND METHODS FOR KEYING FOR DIFFERENTLY-SIZED INFORMATION HANDLING RESOURCES

(71) Applicant: Dell Products L.P., Round Rock, TX (US)

(72) Inventors: Robert G. BASSMAN, Dalton, MA (US); Eduardo ESCAMILLA, Round Rock, TX (US); James UTZ, Georgetown, TX (US); Bernard D. STRMISKA, Georgetown, TX (US)

(73) Assignee: Dell Products L.P., Round Rock, TX (US)

(21) Appl. No.: 18/410,709

(22) Filed: Jan. 11, 2024

(51) Int. Cl. G06F 1/18; H05K 7/14

(52) U.S. Cl. CPC G06F 1/188; H05K 7/1455

(57) ABSTRACT

An information handling system may include a motherboard, an information handling resource bay, a first connector coupled to the motherboard and configured to electrically couple to a compatible information handling resource inserted into the information handling resource bay, and a mechanical guard coupled to the information handling resource bay such that the mechanical guard covers a portion of an opening of the information handling resource bay proximate to the first connector, wherein the mechanical guard is arranged relative to the opening such that when an attempt is made to insert an incompatible information handling resource into the information handling resource bay, the mechanical guard mechanically interferes with an interference feature of the incompatible information handling resource to prevent full insertion of a second connector of the incompatible information handling resource into the first connector.

### TECHNICAL FIELD

The present disclosure relates in general to information handling systems, and more particularly to systems and methods for keying differently-sized information handling resources to prevent connectivity between incompatible connectors.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may include one or more power supply units for providing electrical energy to components of the information handling system. Such power supply systems may come in differently-sized form factors (e.g., 60 mm and 73.5 mm) and the different form factors may be configured to electrically couple to different connectors. In some instances, coupling of a power supply unit to an incompatible connector may lead to undesirable results, including electrical shorts that could damage the power supply unit or the information handling system.

Existing approaches to ensure proper connectivity have included connectors with keying features to ensure proper alignment of power supply units to connectors and to prevent improper coupling of power supply units to incompatible connectors. However, in some instances, including certain industry standards, connectors may not include such keying features, meaning other approaches must provide proper alignment.

### SUMMARY

In accordance with the teachings of the present disclosure, the disadvantages and problems associated with existing approaches to ensuring correct coupling of power supply systems to connectors may be reduced or eliminated.

In accordance with embodiments of the present disclosure, an information handling system may include a motherboard, an information handling resource bay, a first connector coupled to the motherboard and configured to electrically couple to a compatible information handling resource inserted into the information handling resource bay, and a mechanical guard coupled to the information handling resource bay such that the mechanical guard covers a portion of an opening of the information handling resource bay proximate to the first connector, wherein the mechanical guard is arranged relative to the opening such that when an attempt is made to insert an incompatible information handling resource into the information handling resource bay, the mechanical guard mechanically interferes with an interference feature of the incompatible information handling resource to prevent full insertion of a second connector of the incompatible information handling resource into the first connector.

In accordance with these and other embodiments of the present disclosure, a system may include an information handling resource bay, and a mechanical guard coupled to the information handling resource bay such that the mechanical guard covers a portion of an opening of the information handling resource bay proximate to a first connector, wherein the mechanical guard is arranged relative to the opening such that when an attempt is made to insert an incompatible information handling resource into the information handling resource bay, the mechanical guard mechanically interferes with an interference feature of the incompatible information handling resource to prevent full insertion of a first connector of the incompatible information handling resource into a second connector proximate to the opening.

In accordance with these and other embodiments of the present disclosure, an information handling resource may include a housing, a first connector extending from the housing at a connector end of the housing, and a mechanical interference feature at the connector end of the housing configured to, when an attempt is made to insert the information handling resource into a second connector incompatible with the first connector, mechanically interfere with a mechanical guard of an information handling resource bay to prevent full insertion of the first connector into the second connector.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2 illustrates a perspective view of selected components of an information handling system, in accordance with embodiments of the present disclosure;

FIG. 3A illustrates a perspective view of an example power supply unit, in accordance with embodiments of the present disclosure;

FIG. 3B illustrates a side elevation view of the example power supply unit depicted in FIG. 3A, in accordance with embodiments of the present disclosure;

FIG. 4 illustrates a perspective view of another example power supply unit, in accordance with embodiments of the present disclosure;

FIG. 5 illustrates an interference feature configured to couple to a power supply unit, in accordance with embodiments of the present disclosure;

FIG. 6 illustrates a perspective view of selected components of an information handling system with the power supply unit of FIGS. 3A and 3B inserted into an incompatible power supply unit bay, in accordance with embodiments of the present disclosure; and

FIG. 7 illustrates a perspective view of selected components of an information handling system with the power supply unit of FIG. 4 inserted into an incompatible power supply unit bay, in accordance with embodiments of the present disclosure.

### DETAILED DESCRIPTION

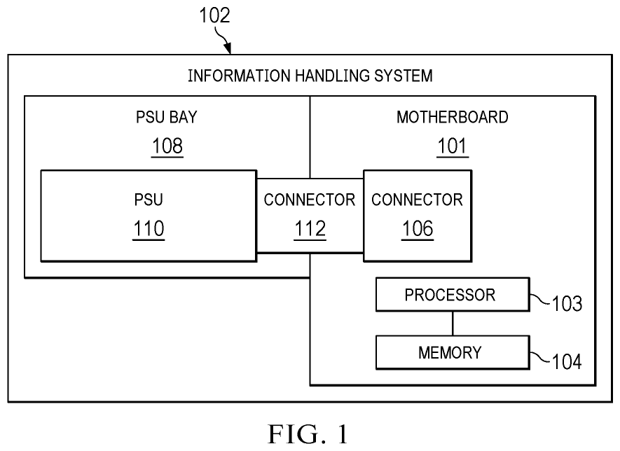

Preferred embodiments and their advantages are best understood by reference to FIGS. 1-7, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal data assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of an example information handling system 102. As depicted, information handling system 102 may include a power supply unit (PSU) 110 housed within a PSU bay 108, a motherboard 101, and one or more other information handling resources.

Motherboard 101 may include a circuit board configured to provide structural support for one or more information handling resources of information handling system 102 and/or electrically couple one or more of such information handling resources to each other and/or to other electric or electronic components external to information handling system 102. As shown in FIG. 1, motherboard 101 may include a processor 103, memory 104, a connector 106, and one or more other information handling resources.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Connector 106 may be mounted upon or otherwise mechanically and electrically coupled to motherboard 110, and may comprise any system, device, or apparatus configured to receive a corresponding connector of PSU 110 in order to electrically couple PSU 110 to motherboard 101. In some embodiments, connector 106 may comprise a receptacle connector configured to receive an edge connector of a circuit board.

PSU bay 108 may comprise a mechanical housing, enclosure, or chassis configured to house PSU 110 and may include any suitable number of mechanical features for guiding connectivity of a connector 112 of PSU 110 to connector 106.

A PSU 110 may include any system, device, or apparatus configured to supply electrical current to one or more information handling resources of information handling system 102.

Connector 112 may be electrically coupled to PSU 110 and may comprise any system, device, or apparatus configured to mechanically and electrically engage with connector 106 in order to electrically couple PSU 110 to motherboard 101.

In addition to motherboard 101, processor 103, memory 104, and PSUs 110, information handling system 102 may include one or more other information handling resources. For example, for purposes of clarity and exposition, only one PSU 110 and associated PSU bay 108, connector 112, and connector 106 is shown in FIG. 1. However, information handling system 102 may include pluralities of PSUs 110, PSU bays 108, connectors 112, and connectors 106.

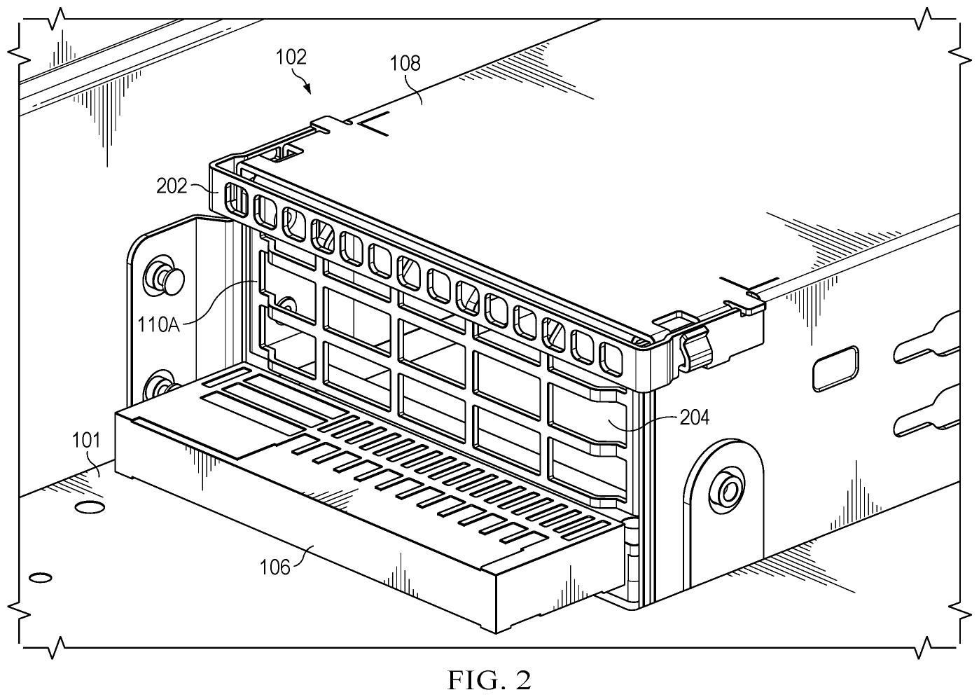

FIG. 2 illustrates a perspective view of selected components of information handling system 102, in accordance with embodiments of the present disclosure. In particular, FIG. 2 illustrates motherboard 101, connector 106, and PSU bay 108 with a PSU 110A inserted into PSU bay 108 which is compatible with PSU bay 108 and connector 106. As shown in FIG. 2, a mechanical guard 202 may be coupled to PSU bay 108 such that mechanical guard 202 covers a portion of an opening 204 of PSU bay 108 proximate to connector 106. As described in greater detail below, mechanical guard 202 may be arranged relative to opening 204 such that when an incompatible PSU 110 having a mechanical interference feature is inserted into PSU bay 108, mechanical guard 202 may prevent full insertion of connector 112 of such PSU 110 into connector 106 of motherboard 101. However, compatible PSU 110A depicted in FIG. 2 may be absent of such a mechanical interference feature, thus allowing connector 112 of PSU 110A (not shown in FIG. 2 because it is fully inserted into connector 106) to be fully inserted into connector 106.

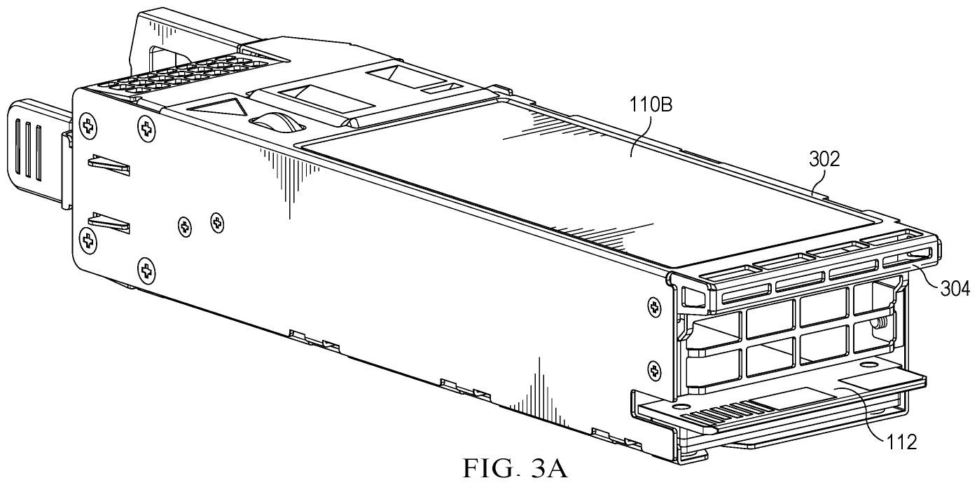

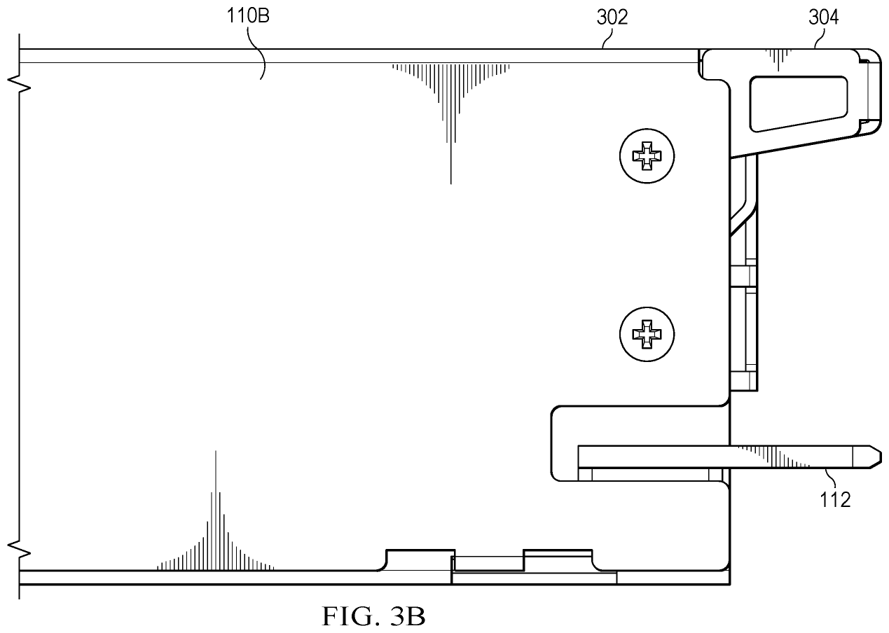

FIG. 3A illustrates a perspective view of an example PSU 110B that is incompatible with connector 106, in accordance with embodiments of the present disclosure. FIG. 3B illustrates a side elevation view PSU 110B, in accordance with embodiments of the present disclosure. As shown in FIGS. 3A and 3B, PSU 110B may include a housing 302 and connector 112 extending from housing 302 at a connector end of housing 302. Further as shown in FIGS. 3A and 3B, housing 302 may have formed therein a bump out feature 304 extending from the connector end of housing 302. As described in greater detail below, bump out feature 304 may serve as a mechanical interference feature that, when an attempt is made to insert PSU 110B into an incompatible PSU bay 108 and incompatible connector 106, mechanical guard 202 may prevent full insertion of connector 112 into connector 106.

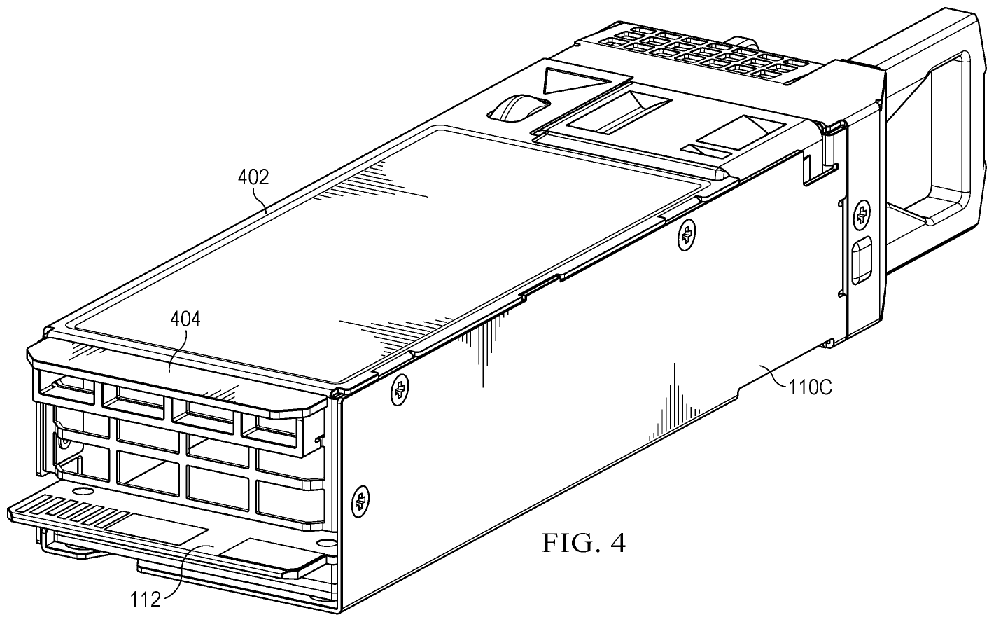

FIG. 4 illustrates a perspective view of another example PSU 110C that is incompatible with connector 106, in accordance with embodiments of the present disclosure. As shown in FIG. 4, PSU 110C may include a housing 402 and connector 112 extending from housing 402 at a connector end of housing 402. Further as shown in FIG. 4, an interference feature 404 may be mechanically coupled to housing 402 at the connector end of housing 402, such that interference feature 404 extends from the connector end of housing 402.

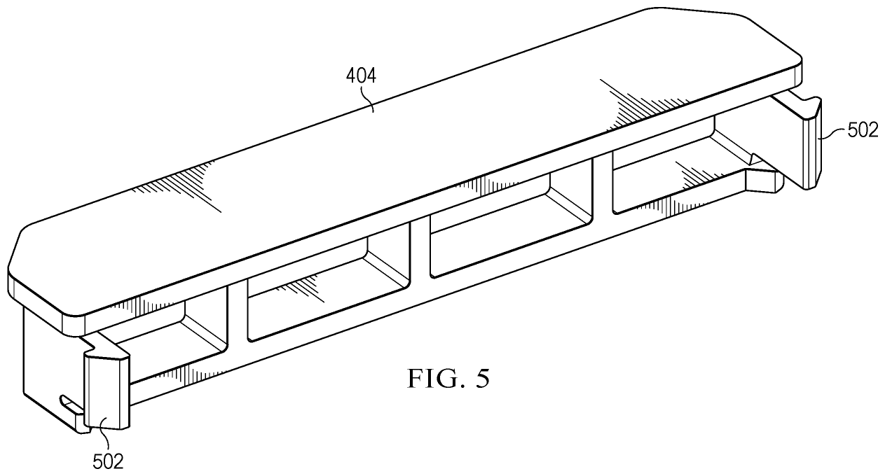

FIG. 5 illustrates an example of interference feature 404. As shown in FIG. 5, interference feature 404 may include mechanical clips 502 or other mechanical features configured to mechanically couple interference feature to housing 402 at the connector end of housing 402.

As described in greater detail below, interference feature 404 may serve as a mechanical interference feature that, when an attempt is made to insert PSU 110C into an incompatible PSU bay 108 and incompatible connector 106, mechanical guard 202 may prevent full insertion of connector 112 into connector 106.

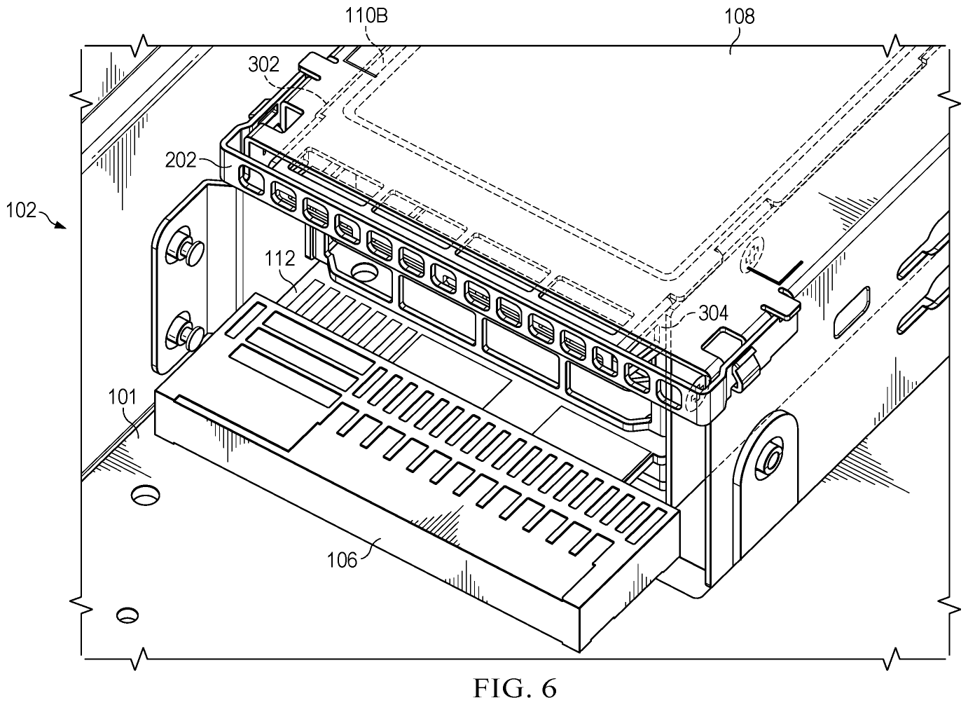

FIG. 6 illustrates a perspective view of selected components of information handling system 102 with PSU 110B inserted into incompatible PSU bay 108, in accordance with embodiments of the present disclosure. As shown in FIG. 6, when an attempt is made to insert PSU 110B into incompatible PSU bay 108 and incompatible connector 106, mechanical guard 202 may prevent full insertion of connector 112 into connector 106.

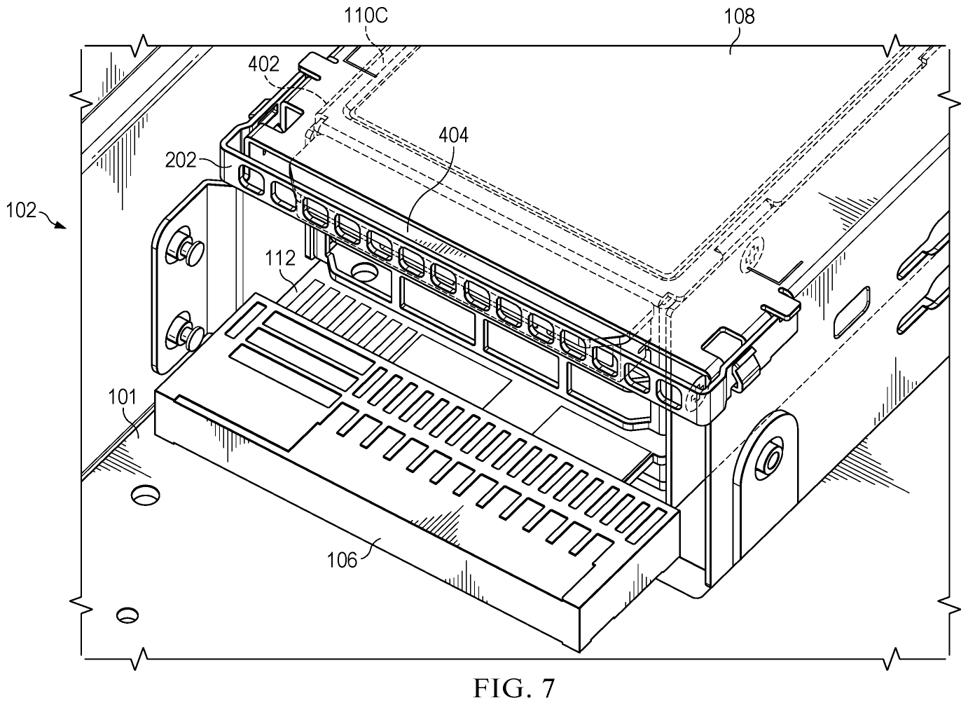

FIG. 7 illustrates a perspective view of selected components of information handling system 102 with PSU 110C inserted into incompatible PSU bay 108, in accordance with embodiments of the present disclosure. As shown in FIG. 7, when an attempt is made to insert PSU 110C into incompatible PSU bay 108 and incompatible connector 106, mechanical guard 202 may prevent full insertion of connector 112 into connector 106.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a motherboard;
an information handling resource bay;
a first connector coupled to the motherboard and configured to electrically couple to a compatible information handling resource inserted into the information handling resource bay; and
a mechanical guard coupled to the information handling resource bay such that the mechanical guard covers a portion of an opening of the information handling resource bay proximate to the first connector, wherein the mechanical guard is arranged relative to the opening such that when an attempt is made to insert an incompatible information handling resource into the information handling resource bay, the mechanical guard mechanically interferes with an interference feature of the incompatible information handling resource to prevent full insertion of a second connector of the incompatible information handling resource into the first connector.

2. The information handling system of claim 1, wherein the compatible information handling resource is a compatible power supply unit configured to be inserted into the information handling resource bay and the first connector.

3. A system comprising:
an information handling resource bay; and
a mechanical guard coupled to the information handling resource bay such that the mechanical guard covers a portion of an opening of the information handling resource bay proximate to a first connector, wherein the mechanical guard is arranged relative to the opening such that when an attempt is made to insert an incompatible information handling resource into the information handling resource bay, the mechanical guard mechanically interferes with an interference feature of the incompatible information handling resource to prevent full insertion of a first connector of the incompatible information handling resource into a second connector proximate to the opening.

4. The system of claim 1, wherein the compatible information handling resource is a compatible power supply unit configured to be inserted into the information handling resource bay and the second connector.

5. An information handling resource, comprising:
a housing;
a first connector extending from the housing at a connector end of the housing; and
a mechanical interference feature at the connector end of the housing configured to, when an attempt is made to insert the information handling resource into a second connector incompatible with the first connector, mechanically interfere with a mechanical guard of an information handling resource bay to prevent full insertion of the first connector into the second connector.

6. The information handling resource of claim 5, wherein the information handling resource comprises a power supply unit.

7. The information handling resource of claim 5, wherein the mechanical interference feature is formed in the housing.

8. The information handling resource of claim 5, wherein the mechanical interference feature comprises a mechanical feature mechanically attached to the housing.
